(19) United States
(12) Patent Application Publication
(10) Pub. No.: US 2024/0339375 A1
(43) Pub. Date: Oct. 10, 2024

(54) HEAT SINK FASTENED ON THE SUBSTRATE OF A PACKAGE OF INTEGRATED CIRCUITS

(71) Applicant: STMicroelectronics International N.V., Geneva (CH)

(72) Inventor: Didier CAMPOS, Charavines (FR)

(73) Assignee: STMicroelectronics International N.V., Geneva (CH)

(21) Appl. No.: 18/624,320

(22) Filed: Apr. 2, 2024

(30) Foreign Application Priority Data
Apr. 7, 2023 (FR) 2303527

(51) Int. Cl. H01L 23/367; H01L 21/48

(52) U.S. Cl. CPC H01L 23/3675; H01L 21/4878

(57) ABSTRACT

An integrated circuit package includes a support substrate and a heat sink. A lateral wall of the heat sink is fastened on a mounting face of the support substrate by fastening devices. The fastening devices are accommodated in compartments of the lateral wall and cross the support substrate through the first orifices. The fastening devices and the first orifices are configured to enable fastening of the lateral wall on the mounting face and permit a relative movement of the fastening devices relative to the first orifices.

### PRIORITY CLAIM

This application claims the priority benefit of French Application for Patent No. 2303527, filed on Apr. 7, 2023, the content of which is hereby incorporated by reference in its entirety to the maximum extent allowable by law.

### TECHNICAL FIELD

Embodiments and implementations relate to the field of electronics and, in particular, to the field of integrated circuit packaging and more particularly fastening heat sinks on the support substrate of integrated circuit packages.

### BACKGROUND

One type of integrated circuit packages, for example a Ceramic Land Grid Array (CLGA) type package comprises a heat sink allowing dissipating the heat produced by the chip of an integrated circuit during operation thereof towards the outside of the package.

The heat sink is typically fastened on a support substrate of the package by means of a glue forming chemical bonds between the heat sink and the support substrate at high temperatures, for example during thermal annealing of the package.

Nonetheless, the material of the support substrate sometimes has a relatively low thermal expansion coefficient (referred to as a Coefficient of Thermal Expansion (CTE)) compared to that of the material of the heat sink such that the latter exerts mechanical stresses on the support substrate. These stresses occur, in particular, at temperatures for which the heat sink expands, for example during thermal annealing of the package, and are typically proportional to the discrepancy between the respective thermal expansion coefficients of the heat sink and of the support substrate. In particular, these stresses could be at the origin of a deformation of the support substrate which may then have a curvature at its ends and not recover its initial flat shape after a decrease in the temperature.

In particularly, the discrepancy between the thermal expansion coefficients is relatively high for the case of a metallic heat sink, for example made of copper, and of a support substrate made of ceramic. In particular, the deformation of the support substrate has been noticed following fastening of heat sinks made of copper whose thermal expansion coefficient is 17×10⁻⁶ K⁻¹ on substrates of CLGA type packages generally made of ceramic such as Alumina (Al₂O₃) whose thermal expansion coefficient is 12×10⁻⁶ K⁻¹.

Consequently, a deformed support substrate is not suitable for mounting the package on a printed circuit board since empty spaces could appear between the curved ends of the package and the printed circuit board once the package is mounted on the board.

Hence, there is a need to find a solution allowing preventing a deformation of the support substrate during fastening of the heat sink on the support substrate.

### SUMMARY

According to one aspect, an integrated circuit package is provided comprising a support substrate and a heat sink including a lateral wall fastened on a mounting face of the support substrate by fastening devices.

The fastening devices are accommodated in compartments of the lateral wall and cross the support substrate through the first orifices. The fastening devices and the first orifices are configured to enable fastening of the lateral wall on the mounting face and a relative movement of the fastening devices relative to the first orifices.

In other words, the heat sink is held fastened to the support substrate by fastening devices whose movement is not completely restricted by the first orifices.

In particular, the fastening devices move freely in the direction of the expansion of the heat sink to prevent the heat sink from exerting mechanical stresses on the support substrate during expansion thereof. And, when the heat sink recovers its initial shape (i.e., when it retracts) the fastening devices can recover their initial position to avoid application of other mechanical stresses on the support substrate when the heat sink retracts.

Thus, the package according to this aspect comprises a heat sink fastened on a support substrate not deforming during an expansion of the heat sink even with significant discrepancies between the thermal expansion coefficients of the support substrate and of the heat sink. Hence, such a package according to this aspect has no curvature at its ends.

In particular, the support substrate may have, for example for a given ceramic type, a thermal expansion coefficient comprised between 10×10⁻⁶ K⁻¹ and 12×10⁻⁶ K⁻¹ and the heat sink may have a thermal expansion coefficient comprised between 15×10⁻⁶ K⁻¹ and 17×10⁻⁶ K⁻¹.

According to one embodiment, the support substrate includes a lower face opposite to the mounting face and the fastening devices comprise rivets each comprising a first end accommodated in a corresponding compartment and a second end under the lower face of the support substrate.

The distance between the first end and the second end is equal to the thickness of the support substrate increased by a clearance enabling both holding the lateral wall fastened to the mounting face of the support substrate and movement of each rivet in the first orifices.

The rivets enable a quick and reliable fastening of the heat sink on the support substrate and are long enough to provide clearance and to facilitate the movement of the rivets in the first orifices.

According to one embodiment, the support substrate includes a lower face opposite to the mounting face and the compartments have a threaded sidewall and the fastening devices comprise screws configured to be screwed into the threaded compartments while leaving a clearance between the screw heads and the lower face of the support substrate.

Advantageously, the screws are used alternatively to the rivets to fasten the heat sink on the support substrate and may be tightened or loosened, and possibly completely removed, for example to be replaced with new screws.

According to one embodiment, the value of the clearance is comprised between 10 and 20 μm.

This clearance range enables the fastening devices to move freely while avoiding creating excessively large spaces between the lateral wall of the heat sink and the mounting face of the support substrate.

According to one embodiment, the first orifices have an oblong shape.

According to one embodiment, the lateral wall of the heat sink has an annular shape with a square or rectangular section, and the support substrate includes four first orifices respectively located opposite the four corner areas of the lateral wall.

This number of first orifices and therefore of fastening devices is enough to reliably fasten a lateral wall having such a shape on the mounting face of the support substrate without any risk of generating mechanical stresses on the support substrate during the expansion of the heat sink.

According to one embodiment, the axis of each first orifice in the plane of the mounting face forms a 45° angle with respect to the direction of the two edges of the lateral wall adjacent to this first orifice.

The oblong shape in combination with the 45° angle, allows orienting the movement of the fastening devices so that they move in the direction of expansion or contraction of the heat sink and confers a greater freedom of movement on the heat sink thereby reducing the stresses on the support substrate.

Thus, the fastening devices can move along the axis of the first orifices.

According to one embodiment, the fastening devices are thermally-conductive.

Thus, the fastening devices allow forming a pathway through the support substrate to dissipate the heat generated by the electronic chips in operation in the package.

According to another aspect, a method for manufacturing an integrated circuit package is provided, comprising: providing a support substrate comprising a mounting face; providing a heat sink comprising a lateral wall; forming compartments in the lateral wall of the heat sink; forming first orifices in the support substrate; and fastening the lateral wall on the mounting face of the support substrate by fastening devices, the fastening devices being accommodated in the compartments of the lateral wall of the heat sink and crossing the support substrate through the first orifices so as to enable a relative movement of the fastening devices relative to the first orifices.

According to one implementation, the support substrate includes a lower face opposite to the mounting face, and fastening of the lateral wall on the mounting face comprises riveting by rivets each comprising a first end accommodated in a corresponding compartment and a second end under the lower face of the support substrate, the distance between the first end and the second end being equal to the thickness of the support substrate increased by a clearance enabling both holding of the lateral wall fastened to the mounting face of the support substrate and movement of each rivet in the first orifices.

According to one implementation, the support substrate includes a lower face opposite to the mounting face, forming the compartments in the lateral wall of the heat sink comprises threading the compartments and fastening the lateral wall on the mounting face comprises screwing with screws into the threaded compartments while leaving a clearance between the screw heads and the lower face of the support substrate.

According to one implementation, the value of the clearance is comprised between 10 and 20 μm.

According to one implementation, the first orifices are made so that they have an oblong shape.

According to one implementation, the heat sink whose lateral wall has an annular shape with a square or rectangular section is provided, and four first orifices are formed in the support substrate respectively located opposite the four corner areas of the lateral wall.

According to one implementation, the axis of each first orifice in the plane of the mounting face forms a 45° angle with respect to the direction of the two edges of the lateral wall adjacent to this first orifice.

According to one implementation, the fastening devices are made so that they are thermally-conductive.

According to one implementation, the support substrate has a thermal expansion coefficient comprised between 10×10⁻⁶ K⁻¹ and 12×10⁻⁶ K⁻¹ and the heat sink has a thermal expansion coefficient comprised between 15×10⁻⁶ K⁻¹ and 17×10⁻⁶ K⁻¹

### BRIEF DESCRIPTION OF THE DRAWINGS

Other advantages and features of the invention will appear upon examining the detailed description of non-limiting embodiments and implementations, and from the appended drawings, wherein:

FIG. 1 schematically illustrates a sectional view of an integrated circuit package;

FIG. 2 schematically illustrates a sectional view of an integrated circuit package;

FIG. 3 schematically illustrates a sectional view of the package described before with reference to FIG. 1;

FIG. 4 illustrates a top view of the package described before with reference to FIG. 1; and

FIG. 5 illustrates a mode of implementation of a method for manufacturing an integrated circuit package.

### DETAILED DESCRIPTION

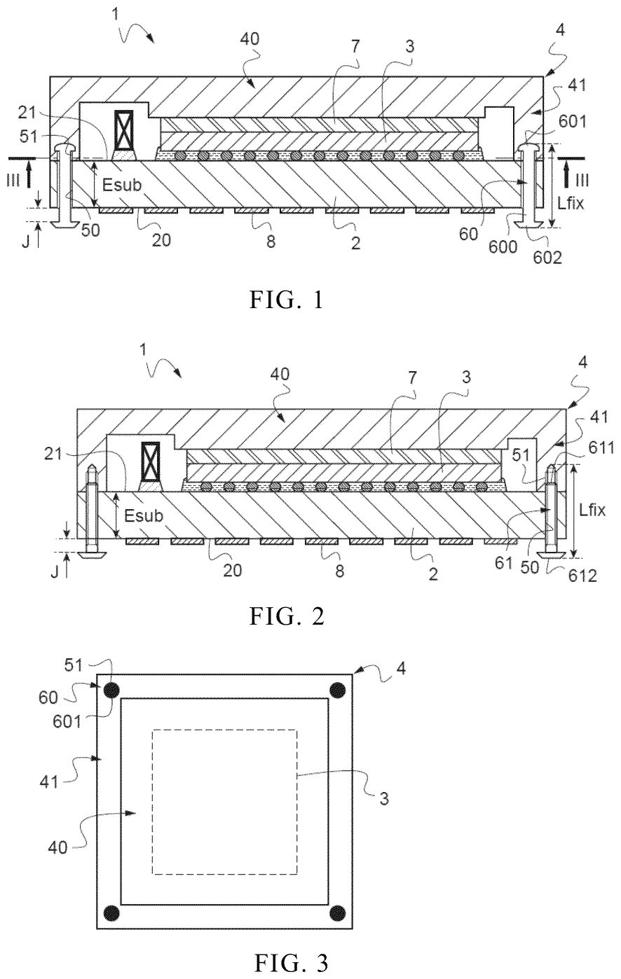

FIG. 1 schematically illustrates a sectional view of an integrated circuit package 1 according to one embodiment.

The package 1 includes a support substrate 2 comprising a mounting face 21 and a lower face 20 opposite to the mounting face.

The support substrate 2 has a conventional structure known per se, and may have a different composition depending on the package type. The support substrate 2 includes conductive tracks, typically made of copper, integrated into one or more dielectric material layer(s). In the case of a “CLGA” type package, the dielectric material is typically ceramic such as Alumina (Al₂O₃) or aluminum nitride (AlN).

In particular, the support substrate 2 may include ceramic fired at low temperature referred to as a Low Temperature Co-Fired Ceramic (LTCC) of the GL773 type commercialized by the Japanese company Kyocera whose thermal expansion coefficient is comprised between 10×10⁻⁶ K⁻¹ and 12×10⁻⁶ K⁻¹, for example 12×10⁻⁶ K⁻¹

The support substrate 2 includes first orifices 50 extending across the thickness Esub of the support substrate 2 between the mounting face 21 and the lower face 20 of the support substrate 2. For example, the thickness Esub of the support substrate 2 is comprised between 3 and 4 mm.

The integrated circuit package 1 also includes at least one electronic integrated circuit chip 3 and a heat sink 4.

The electronic chip(s) 3 may be mounted and connected to the mounting face 21 of the support substrate 2 in a conventional manner known per se, for example by soldering connection beads.

The heat sink 4 includes a lateral wall 41 and an upper wall 40. The lateral wall 41 is fastened on the mounting face 21 of the support substrate 2 by fastening devices 60 and the upper wall 40 is herein fastened on the electronic chip 3 via an interface material 7 that is preferably thermally-conductive. The lateral wall 41 comprises compartments 51, for example orifices (or blind openings) extending partially into the lateral wall 41 and aligned with the first orifices 50 of the support substrate 2.

Furthermore, the heat sink 4 is made of metal, for example of copper (Cu), and then has a thermal expansion coefficient equal to 17×10⁻⁶ K⁻¹. Consequently, the expansion of the heat sink 4 is more significant than that of the support substrate at high temperatures, in particular during thermal annealing of the package and would have exerted mechanical stresses on the support substrate if the lateral wall has been fastened to the mounting face with glue for example like in the prior art.

According to embodiments herein, the fastening devices and the first orifices 50 are configured to enable fastening of the lateral wall 41 on the mounting face 21 and a relative movement of the fastening devices relative to the first orifices 50, in the plane of the mounting face 21. In particular, the fastening devices cross the support substrate 2 through the first orifices 50 and are accommodated in the compartments 51 of the lateral wall 41.

In other words, the heat sink 4 is held fastened to the support substrate 2 by fastening devices whose movement is not completely restricted by the first orifices 50.

The fastening devices, moving freely in the direction of the expansion of the heat sink 4, prevent the heat sink 4 from exerting mechanical stresses on the support substrate 2 during expansion thereof, for example at high temperatures. And, when the heat sink 4 recovers its initial shape (i.e., when it retracts in particular during a decrease in the temperature), the fastening devices can recover their initial position to avoid application of other mechanical stresses on the support substrate 2.

Thus, the support substrate 2 of the package 1 according to this aspect does not deform during an expansion or a contraction of the heat sink 4 even in the presence of the aforementioned discrepancies between the thermal expansion coefficients of the support substrate 2 and of the heat sink 4.

Moreover, the support substrate 2 of this package 1 has no curvature at its ends and remains flat so that, when the package 1 is fastened on a printed circuit board, the space between the lower face 20 of the support substrate and the printed circuit board is minimized.

The fastening devices, as shown in FIG. 1, comprise rivets 60 each comprising a first end 601 and a second end 602 as well as a body 600 joining the first end 601 and the second end 602. The first end 601 of each rivet 60 is accommodated in a corresponding compartment 51 of the lateral wall 41 and the second end 602 of each rivet 60 is located under (and offset by a clearance J from) the lower face 20 of the support substrate 2.

Advantageously, the distance Lfix between the first end 601 and the second end 602 is equal to the thickness Esub of the support substrate 2 increased by the clearance J. The clearance J enables both holding the lateral wall 41 fastened to the mounting face 21 of the support substrate 2 and movement of each rivet 60 in the first orifices 50.

Advantageously, the value of the clearance J is comprised between 10 and 20 μm. This clearance J range enables the rivets 60 to move freely while avoiding creating excessively large spaces between the lateral wall 41 of the heat sink 4 and the mounting face 21 of the support substrate 2.

A person skilled in the art would know how to adapt the dimensions of the rivets 60 and of the first orifices 50 to obtain such clearance J values and to enable a relative movement of the rivets relative to the first orifices 50.

Furthermore, the first end 601 and the second end 602 of the rivets 60 are configured to hold the lateral wall 41 fastened to the mounting face 21 and move just very slightly along the height of the support substrate 2.

Advantageously, the rivets 60 are thermally-conductive and thus allow forming a pathway through the support substrate 2 to dissipate the heat generated by the electronic chips 3 in operation in the package 1.

FIG. 2 schematically illustrates a sectional view of an integrated circuit package 1 according to one variant. The heat sink and the support substrate, similar to those described before, bear the same references.

According to this variant, only the compartments 51 of the lateral wall 41 and the fastening devices have been changed so that the compartments 51 have a threaded sidewall and the fastening devices comprise screws 61. The screws 61 are configured to be screwed into the threaded compartments 51 while leaving a clearance J between the screw heads 602 and the lower face 20 of the support substrate 2.

All what has been described before for the package 1 of FIG. 1, in particular the advantages related to fastening of the lateral wall on the mounting face and to the relative movement of the fastening devices relative to the first orifices, applies to the package 1 of FIG. 2.

More particularly, the screws 61 cross the support substrate 2 through the first orifices 50 and have a threaded end 611 screwed into the corresponding threaded compartment 51.

Furthermore, the clearance J between the screw heads 602 and the lower face 20 may be comprised in the same value range, between 10 and 20 μm, as the clearance described before with reference to FIG. 1.

A person skilled in the art would know how to adapt the dimensions of the screws 61 with respect to the dimensions of the first orifices 50 to obtain such clearance J values and to enable a relative movement of the screws 61 relative to the first orifices 50.

The screws 61 may be tightened or loosened, for example to adjust the value of the clearance J, and even completely removed to be replaced with new screws.

Advantageously, the screws 61 are also thermally-conductive and thus allow forming a pathway through the support substrate 2 to dissipate the heat generated by the electronic chips 3 in operation in the package 1.

FIG. 3 schematically illustrates a sectional view of the package 1 described before with reference to FIG. 1 according to the axis III-III.

The lateral wall 41 of the heat sink 4 has an annular shape with a square or rectangular section and comprises four compartments 51 located in the four corner areas of the lateral wall 41

Each compartment 51 allows blocking the movement of the fastening devices relative to the lateral wall 41. For example, the compartment has an opening in the lateral wall 41 opening onto a cavity in which the second end 602 of the rivet 60 is accommodated and being narrow enough so as to hold the second end 602 in the cavity.

In the alternative illustrated in FIG. 2, the threaded sidewalls of the compartments 51 allows holding the threaded end 611 of the screw 61 and thus blocking the movement of the screw 61 relative to the lateral wall 41.

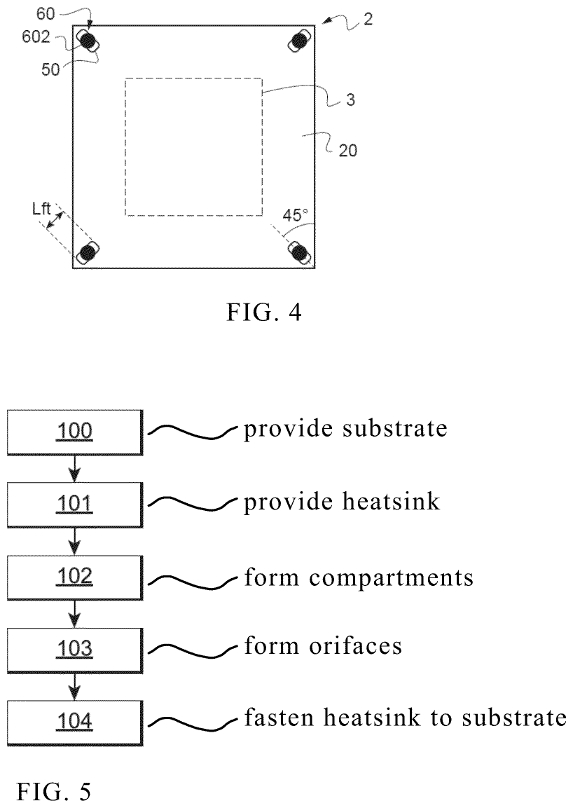

FIG. 4 illustrates a top view of the package 1 described before with reference to FIG. 1.

The support substrate 2 includes four first orifices 50 respectively located opposite the four corner areas of the lateral wall 41.

Preferably, the first orifices 50 have an oblong shape with a length Lft, larger than the diameter of the body 600 of the rivets 60 (or body of the screws) so that the rivets 60 (or screws) could move freely, in the plane of the mounting face 21, during an expansion or a contraction of the heat sink 4.

The axis of each first orifice 50 in the plane of the mounting face 21 forms a 45° angle with respect to the direction of the two edges of the lateral wall 41 adjacent to this first orifice 50. Thus, the rivets 60 (or screws) can move along the axis of the first orifices 50.

The oblong shape of the first orifices 50, in combination with the 45° angle, allows orienting the movement of the rivets 60 (or screws) in the direction of the expansion or of the contraction of the heat sink 4 and confers more freedom of movement on the heat sink 4.

The number of compartments 51 and of first orifices 50 as well as their respective shape and positioning in the lateral wall 41 and in the support substrate 2 may vary and depend for example on the shape of the lateral wall 41 of the heat sink to be fastened on the mounting face 21 of the support substrate 2.

FIG. 5 illustrates a mode of implementation of a method for manufacturing an integrated circuit package 1. For example, such a manufacturing method is used to manufacture a package 1 as shown in FIG. 1 or in FIG. 2.

The method comprises providing 100 a support substrate 2 comprising a mounting face 21 and a lower face 20 opposite to the mounting face 21. The support substrate 2 has a thickness Esub and includes conductive tracks, typically made of copper, integrated in one or more dielectric material layer(s) which may consist of ceramic such as Alumina (Al₂O₃) or aluminum nitride (AlN). The thermal expansion coefficient of such a support substrate 2 of such a package amounts to about 12×10⁻⁶ K⁻¹.

The method also comprises providing 101 a heat sink 4 comprising a lateral wall 41, for example with an annular shape with a square or rectangular section. Furthermore, the heat sink 4 is made of metal, for example of copper (Cu), and has a thermal expansion coefficient equal to about 17×10⁻⁶ K⁻¹.

The method further comprises forming 102 compartments 51 in the lateral wall 41 of the heat sink 4 and forming 103 first orifices 50 in the support substrate 2. More particularly, forming 102 compartments 51 in the lateral wall 41 comprises threading the compartments 51 in the case of manufacture of the package 1, described with reference to FIG. 2.

Advantageously, four first orifices 50 are formed in the support substrate 2 and four compartments 51 in the lateral wall 41 so that the first orifices 50 are respectively located opposite the four corner areas of the lateral wall 41 and aligned with the respective compartments 51 during fastening of the lateral wall 41.

Furthermore, the first orifices 50 have an oblong shape. Forming 103 the first orifices 50 may be carried out in parallel with the steps of providing 101 the heat sink and of forming 102 compartments 51 or possibly well before or after step 101 and/or step 102.

Afterwards, the method comprises fastening 104 the lateral wall 41 on the mounting face 21 of the support substrate 2 by fastening devices such as rivets 60 or screws 61, which may be thermally-conductive. The fastening devices are accommodated in the compartments 51 of the lateral wall 41 of the heat sink 4 and cross the support substrate 2 through the first orifices 50 so as to enable a relative movement of the fastening devices relative to the first orifices 50.

In the case of manufacture of the package 1 described before with reference to FIG. 1, fastening 104 comprises riveting with rivets 60 each comprising a first end 601 accommodated in a corresponding compartment 51 and a second end 602 under the lower face 20 of the support substrate 2. The distance Lfix between the first end 601 and the second end 602 is equal to the thickness Esub of the support substrate increased by a clearance J enabling both holding the lateral wall 41 fastened to the mounting face 21 of the support substrate 2 and movement of each rivet 60 in the first orifices 50.

In the case of manufacture of the package 1 described before with reference to FIG. 2, fastening 104 comprises screwing with screws 61 in the threaded compartments 51 while leaving a clearance J between the screw heads 602 and the lower face 20 of the support substrate 2. Preferably, the value of the clearance J is comprised between 10 and 20 μm.

The axis of each first orifice 50 in the plane of the mounting face 21 forms a 45° angle with respect to the direction of the two edges of the lateral wall 41 adjacent to this first orifice 50.

1. An integrated circuit package, comprising:
a support substrate; and
a heat sink including a lateral wall fastened on a mounting face of the support substrate by fastening devices;
wherein the fastening devices are accommodated in compartments of the lateral wall and cross the support substrate through first orifices; and
wherein the fastening devices and the first orifices are configured to enable fastening of the lateral wall on the mounting face and a relative movement of the fastening devices relative to the first orifice.

2. The package according to claim 1, wherein the support substrate includes a lower face opposite to the mounting face and wherein the fastening devices comprise rivets, each rivet comprising a first end accommodated in a corresponding compartment and a second end under the lower face of the support substrate, wherein a distance between the first end and the second end is equal to a thickness of the support substrate increased by a clearance enabling both holding of the lateral wall fastened to the mounting face of the support substrate and movement of each rivet in the first orifice.

3. The package according to claim 2, wherein the value of the clearance is comprised between 10 and 20 μm.

4. The package according to claim 1, wherein the support substrate includes a lower face opposite to the mounting face and wherein the compartments are threaded and the fastening devices comprise screws configured to be screwed into the threaded compartments while leaving a clearance between the screw heads and the lower face of the support substrate.

5. The package according to claim 4, wherein the value of the clearance is comprised between 10 and 20 μm.

6. The package according to claim 1, wherein the first orifices have an oblong shape.

7. The package according to claim 6, wherein an axis of each first orifice with the oblong shape in the plane of the mounting face forms a 45° angle with respect to the direction of the two edges of the lateral wall adjacent to this first orifice.

8. The package according to claim 1, wherein the lateral wall of the heat sink has an annular shape with a square or rectangular section, and the support substrate includes four first orifices respectively located opposite four corner areas of the lateral wall.

9. The package according to claim 1, wherein the fastening devices are thermally-conductive.

10. The package according to claim 1. wherein the support substrate has a thermal expansion coefficient comprised between 10×10⁻⁶ K⁻¹ and 12×10⁻⁶ K⁻¹ and the heat sink has a thermal expansion coefficient comprised between 15×10⁻⁶ K⁻¹ and 17×10⁻⁶ K⁻¹.

11. A method for manufacturing an integrated circuit package, comprising:
providing a support substrate comprising a mounting face;
providing a heat sink comprising a lateral wall;
forming compartments in the lateral wall of the heat sink;
forming first orifices in the support substrate; and
fastening the lateral wall on the mounting face of the support substrate by fastening devices, the fastening devices being accommodated in the compartments of the lateral wall of the heat sink and crossing the support substrate through the first orifices so as to enable a relative movement of the fastening devices relative to the first orifices.

12. The method according to claim 11, wherein the support substrate includes a lower face opposite to the mounting face, wherein fastening the lateral wall on the mounting face comprises riveting by rivets, wherein each rivet comprises a first end accommodated in a corresponding compartment and a second end under the lower face of the support substrate, wherein a distance between the first end and the second end is equal to a thickness of the support substrate increased by a clearance enabling both holding of the lateral wall fastened to the mounting face of the support substrate and movement of each rivet in the first orifice.

13. The method according to claim 12, wherein the value of the clearance is comprised between 10 and 20 μm.

14. The method according to claim 11, wherein the support substrate includes a lower face opposite to the mounting face, wherein forming the compartments in the lateral wall of the heat sink comprises threading the compartments, and wherein fastening the lateral wall on the mounting face comprises screwing with screws into the threaded compartments while leaving a clearance between the screw heads and the lower face of the support substrate.

15. The method according to claim 14, wherein the value of the clearance is comprised between 10 and 20 μm.

16. The method according to claim 11, wherein forming first orifices comprises forming each first orifice to have an oblong shape.

17. The method according to claim 15, wherein an axis of each oblong shape first orifice in the plane of the mounting face forms a 45° angle with respect to the direction of the two edges of the lateral wall adjacent to this first orifice.

18. The method according to claim 11, wherein the heat sink has a lateral wall with an annular shape of a square or rectangular section, and wherein forming first orifices comprises forming four first orifices in the support substrate respectively located opposite the four corner areas of the lateral wall.

19. The method according to claim 11, wherein the fastening devices are thermally-conductive.

20. The method according to claim 11. wherein the support substrate has a thermal expansion coefficient comprised between 10×10⁻⁶ K⁻¹ and 12×10⁻⁶ K⁻¹ and the heat sink has a thermal expansion coefficient comprised between 15×10⁻⁶ K⁻¹ and 17×10⁻⁶ K⁻¹.
